(19) United States
(12) Patent Application Publication
(10) Pub. No.: US 2026/0198330 A1
(43) Pub. Date: Jul. 9, 2026

(54) SEMICONDUCTOR PACKAGE HAVING CAPACITORS AND TWO OR MORE DRIVER DEVICES AND METHOD OF MAKING THE SAME

(71) Applicant: ALPHA AND OMEGA SEMICONDUCTOR INTERNATIONAL LP, TORONTO (CA)

(72) Inventors: Yan Xun Xue, Los Gatos, CA (US); Zhiqiang Niu, Santa Clara, CA (US); Madhur Bobde, Sunnyvale, CA (US); Long-Ching Wang, Cupertino, CA (US)

(73) Assignee: ALPHA AND OMEGA SEMICONDUCTOR INTERNATIONAL LP, TORONTO (CA)

(21) Appl. No.: 19/551,425

(22) Filed: Feb. 26, 2026

Related U.S. Application Data
(63) Continuation-in-part of application No. 18/666,385, filed on May 16, 2024.

(51) Int. Cl. H10W 44/00; H10D 80/20; H10D 80/30; H10W 40/20; H10W 40/25; H10W 70/04; H10W 70/40; H10W 74/01; H10W 74/10; H10W 90/00; H10W 90/10

(52) U.S. Cl. CPC H10W 44/601; H10W 40/235; H10W 40/258; H10W 70/041; H10W 70/411; H10W 70/461; H10W 70/464; H10W 70/475; H10W 70/481; H10W 74/014; H10W 74/114; H10W 90/10; H10W 90/811; H10D 80/215; H10D 80/251; H10D 80/30; H10W 90/756

(57) ABSTRACT

A semiconductor package comprises a lead frame, two or more low side field-effect transistor (FET) chips, two or more high side FET chips, two or more metal clips, an integrated circuit (IC) chip, one or more capacitors, a plurality of bond wires, and a molding encapsulation. A method for fabricating a semiconductor package comprising the steps of providing a lead frame comprising die paddles; attaching transistor chips to the die paddles; mounting metal clips; attaching capacitors; mounting an IC chip, applying bonding wires; forming a molding encapsulation; and applying a singulation process.

### CROSS-REFERENCE TO RELATED APPLICATIONS

This Patent Application is a Continuation-in-part application of a pending U.S. patent application Ser. No. 18/666,385 filed on May 16, 2024. The Disclosure made in U.S. patent application Ser. No. 18/666,385 is hereby incorporated by reference.

### FIELD OF THE INVENTION

This invention relates generally to a semiconductor package and a method of making the same. More particularly, the present invention relates to the semiconductor package having capacitors and two or more driver devices and the method of making the same.

### BACKGROUND OF THE INVENTION

Conventional circuit to provide power for a central processing unit (CPU) or a graphics processing unit (GPU) includes a plurality of driver metal-oxide-semiconductors (DrMOSs). The plurality of DrMOSs take space and increase impedance. U.S. patent application Ser. No. 18/666,385 reduces a semiconductor package size to 5 mm by 4 mm by using common Vcc pin, TMON pin, AGND pin, and PVcc pin. But, conventional DrMOSs require electrical connections to external capacitors thereby introducing additional impedance, reducing efficiency, and adding additional processing steps.

The instant disclosure integrates capacitors in the semiconductor package thereby eliminating additional impedance, increasing efficiency, and removing additional processing steps. The instant disclosure further reduces total number of capacitors.

### SUMMARY OF THE INVENTION

The present invention discloses a semiconductor package comprising a lead frame, two or more low side field-effect transistor (FET) chips, two or more high side FET chips, two or more metal clips, an integrated circuit (IC) chip, one or more capacitors, a plurality of bond wires, and a molding encapsulation.

A method for fabricating a semiconductor package is also disclosed. The method comprises the steps of providing a lead frame comprising die paddles; attaching transistor chips to the die paddles; mounting metal clips; attaching capacitors; mounting an IC chip, applying bonding wires; forming a molding encapsulation; and applying a singulation process.

### BRIEF DESCRIPTION OF THE DRAWINGS

FIG. 1 is a schematic plot of circuit to provide power for a CPU or a GPU in examples of the present disclosure.

FIG. 2A is a top perspective view and FIG. 2B is a bottom perspective view of a semiconductor package in examples of the present disclosure.

FIG. 3A is a top view and FIG. 3B is a top perspective view of a semiconductor package in examples of the present disclosure.

FIG. 4 is a flowchart of a process to develop a semiconductor package in examples of the present disclosure.

FIGS. 5A, 5B, 5C, 5D, 5E, and 5F show top views, and FIGS. 5G and 5H show perspective views of steps of the process to fabricate the semiconductor package in examples of the present disclosure.

### DETAILED DESCRIPTION OF THE INVENTION

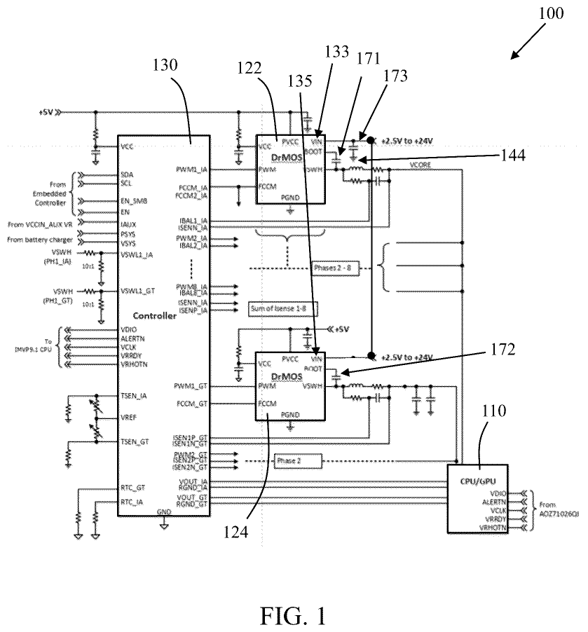

FIG. 1 is a schematic plot of circuit 100 to provide power for a CPU or a GPU 110. The circuit 100 includes a first DrMOS 122 including a driver circuit and a high side MOSFET and a low side MOSFET, a second DrMOS 124 including a driver circuit and a high side MOSFET and a low side MOSFET, a controller 130, a plurality of capacitors including a first bootstrap capacitor 171, a second bootstrap capacitor 172, and an input capacitor 173. The advantage of the instant disclosure is to co-pack one or more capacitors in a single package, to minimize or eliminate electrical connections to external capacitors and to reduce total number of capacitors. FIG. 1 of the instant disclosure includes a single input capacitor 173 between a first input voltage (Vᵢₙ) pin 133 and the power ground 144 [PGND pin], and between a second Vᵢₙ pin 135 and the power ground 144. The single input capacitor 173 of the instant disclosure is shared by the first Vᵢₙ pin 133 and the power ground 144, and the second Vᵢₙ pin 135 and the power ground 144. For comparison, FIG. 1 of U.S. patent application Ser. No. 18/666,385, using external capacitors, requires two separate capacitors (one between Vᵢₙ of DrMOS 122 and the power ground, and the other one between Vᵢₙ of DrMOS 124 and the power ground). Therefore, the instant disclosure reduces the number of capacitors by one.

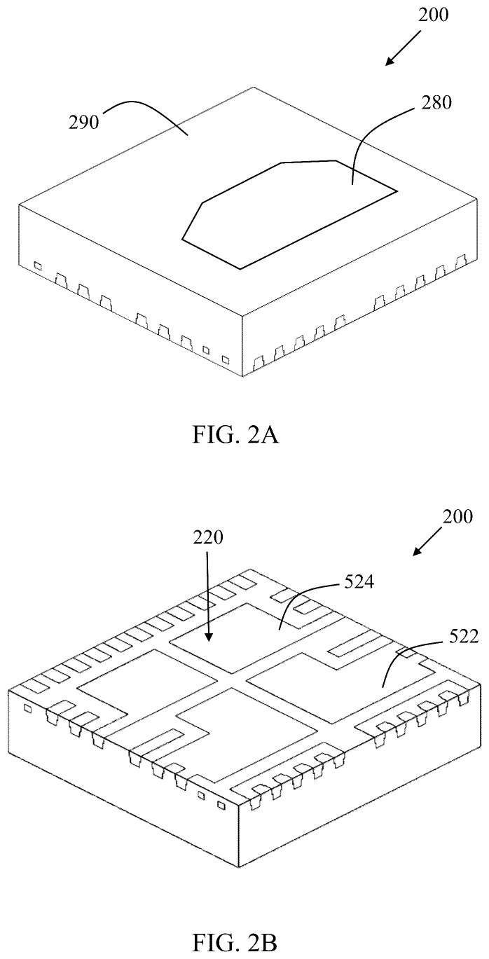

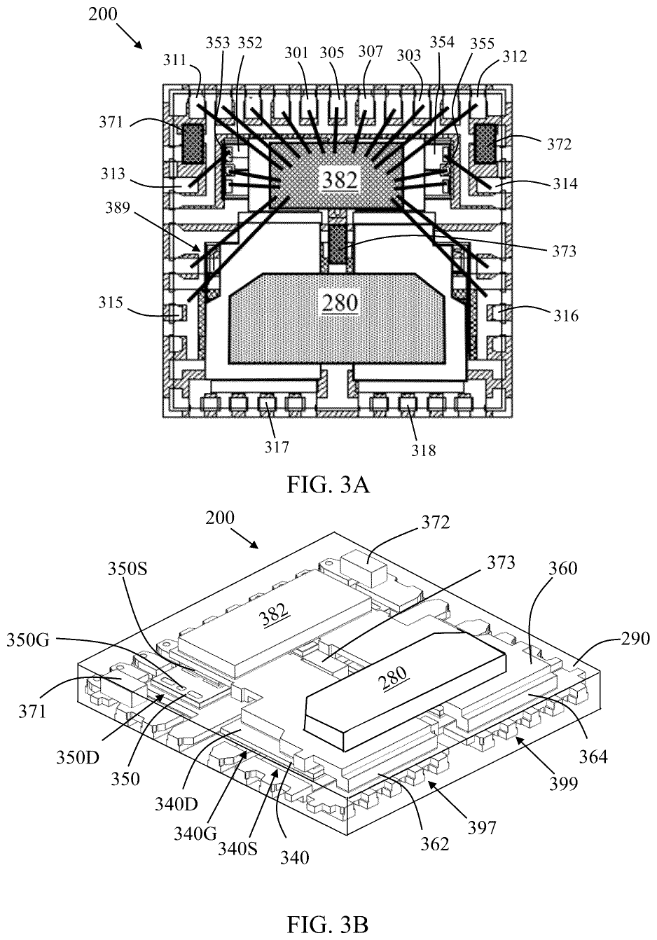

FIG. 2A is a top perspective view and FIG. 2B is a bottom perspective view of a semiconductor package 200 in examples of the present disclosure. FIG. 3A is a top view and FIG. 3B is a top perspective view of the semiconductor package 200, having the molding encapsulation 290 shown in transparent, in examples of the present disclosure. The semiconductor package 200 comprises a lead frame 220, two or more low side field-effect transistor (FET) chips 340, two or more high side FET chips 350, two or more metal clips 360, an integrated circuit (IC) chip 382, a first bootstrap capacitor 371, a second bootstrap capacitor 372, and an input capacitor 373, and a molding encapsulation 290. The semiconductor package 200 may optionally further comprises, a metal slug 280, and a plurality of bond wires 389. In one example of the invention, the IC chip 382 includes a driver circuit. In another example of the invention, the IC chip 382 includes dual driver circuits. In another example of the invention, the IC chip 382 further includes a controller circuit of controller 130 of FIG. 1.

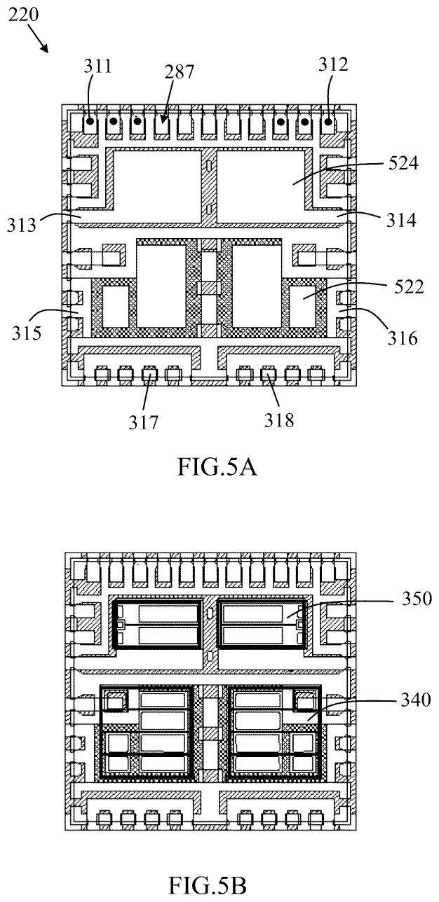

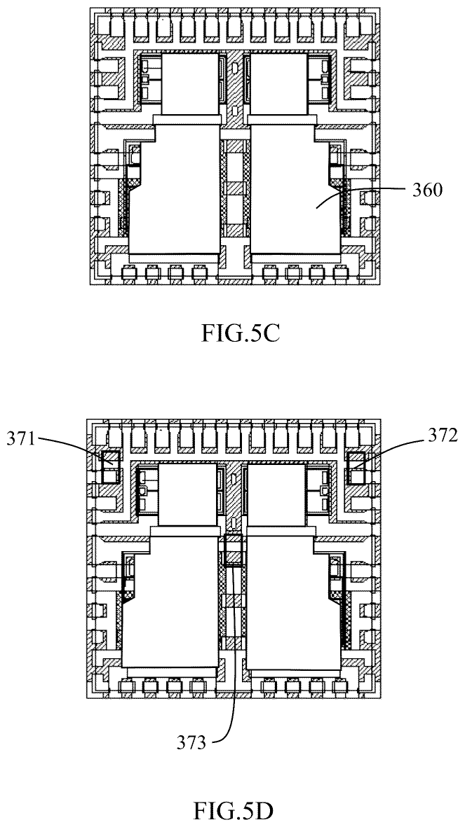

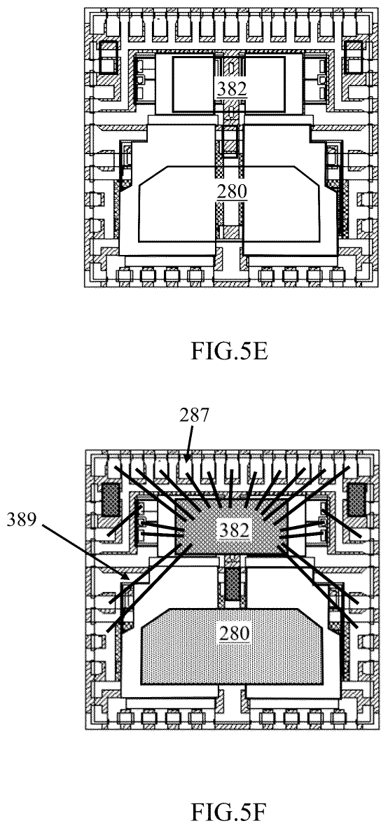

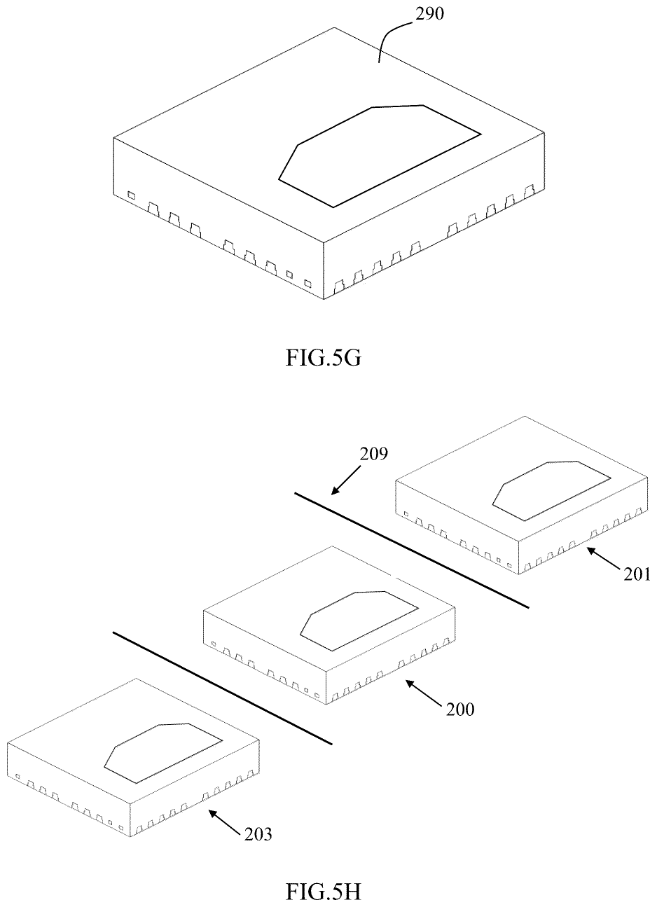

The lead frame 220 comprises a first die paddle 522 of FIG. 5A and a second die paddle 524 of FIG. 5A.

Each low side FET chip of the two or more low side FET chips 340 is flipped and attached to the first die paddle 522 of FIG. 5A. Each low side FET chip of the two or more low side FET chips 340 comprises a source electrode 340S and a gate electrode 340G on a top surface of said each low side FET chip of the two or more low side FET chips 340. Each low side FET chip of the two or more low side FET chips 340 comprises a drain electrode 340D on a bottom surface of said each low side FET chip of the two or more low side FET chips 340.

Each high side FET chip of the two or more high side FET chips 350 is attached to the second die paddle 524 of FIG. 5A. Each high side FET chip of the two or more high side FET chips 350 comprises a source electrode 350S and a gate electrode 350G on a top surface of said each high side FET chip of the two or more high side FET chips 350. Each high side FET chip of the two or more high side FET chips 350 comprises a drain electrode 350D on a bottom surface of said each high side FET chip of the two or more high side FET chips 350.

Each metal clip of the two or more metal clips 360 connects the drain electrode 340D of a respective low side FET chip of the two or more low side FET chips 340 to the source electrode 350S of a respective high side FET chip of the two or more high side FET chips 350.

The metal slug 280 is positioned above the two or more low side FET chips 340. Each metal clip of the two or more metal clips 360 is attached to the metal slug 280.

The IC chip 382 is positioned above the two or more high side FET chips 350. Each metal clip of the two or more metal clips 360 is attached to the IC chip 382.

The lead frame 220 further comprises a first boot pin 311, a second boot pin 312, a first switch node voltage (VSWH) pin 317, and a second VSWH pin 318. The two or more high side FET chips 350 comprises a first high side FET chip 352 comprising a VSWH pad 353 on the top surface connected to the source electrode of the first high side FET chip 352, and a second high side FET chip 354 comprising a VSWH pad 355 on the top surface connected to the source electrode of the second high side FET chip 354. The first bootstrap capacitor 371 comprises a first side electrically connecting with the first boot pin 311 of the lead frame 220, and a second side electrically connecting with the VSWH pad 353 of the first high side FET chip 352. The second bootstrap capacitor 372 comprises a first side electrically connecting with the second boot pin 312 of the lead frame 220, and a second side electrically connecting with the VSWH pad 355 of the second high side FET chip 354.

The two or more metal clips 360 comprises a first metal clip 362 and a second metal clip 364. The first metal clip 362 electrically connects the VSWH pad 353 of the first high side FET chip 352 and the drain electrode of the first low side FET to the first VSWH pin 317 of the lead frame 220. The second metal clip 364 electrically connects the VSWH pad 355 of the second high side FET chip 354 to the second VSWH pin 318 of the lead frame 220.

The lead frame 220 further comprises a first input voltage (Vᵢₙ) pin 313, a second Vᵢₙ pin 314, a first output voltage power ground (PGND) pin 315, and a second PGND pin 316. The input capacitor 373 comprises a first side electrically connecting with the first Vᵢₙ pin 313 of the lead frame 220 and the second Vᵢₙ pin 314 of the lead frame 220, and a second side electrically connecting with the first PGND pin 315 of the lead frame 220 and the second PGND pin 316 of the lead frame 220.

In examples of the present disclosure, the semiconductor package 200 consists of three capacitors only (the first bootstrap capacitor 371, the second bootstrap capacitor 372, and the input capacitor 373). The semiconductor package 200 excludes a fourth capacitor.

No capacitors, other than the input capacitor 373, is between the first Vᵢₙ pin 313 of the lead frame 220 and the first PGND pin 315 of the lead frame 220, and is between the second Vᵢₙ pin 314 of the lead frame 220 and the second PGND pin 316 of the lead frame 220.

In examples of the present disclosure, the input capacitor 373 is positioned above a center of the lead frame 220.

The molding encapsulation 290 encloses the two or more low side FET chips 340, the two or more high side FET chips 350, the two or more metal clips 360, the IC chip 382, the first bootstrap capacitor 371, the second bootstrap capacitor 372, the input capacitor 373, the plurality of bond wires 389, and a majority portion of the lead frame 220. In examples of the present disclosure, the majority portion refers to a percentage larger than 50%. The molding encapsulation 290 may further encloses a majority portion of the metal slug 280.

A first significant portion of a bottom surface of the first die paddle 522 is exposed from the molding encapsulation 290. A second significant portion of a bottom surface of the second die paddle 524 is exposed from the molding encapsulation 290. In examples of the present disclosure, the first significant portion refers to a percentage larger than 90%. The second significant portion refers to a percentage larger than 90%. A top surface of the metal slug 280 is exposed from the molding encapsulation 290 so as to facilitate heat dissipation.

In examples of the present disclosure, the semiconductor package 200 further comprises a plurality of bond wires 389 of FIG. 5H. The lead frame 220 further comprises a plurality of leads 287 of FIG. 5A. The plurality of bond wires 389 connect the IC chip 382 to the plurality of leads 287. The molding encapsulation 290 further encloses the plurality of bond wires 389.

The semiconductor package comprises two or more driver devices. In examples of the present disclosure, semiconductor package 200 comprises a first driver device 397 and a second driver device 399. Each driver device of the two or more driver devices of the semiconductor package 200 comprises a respective low side FET chip of the two or more low side FET chips 340, a respective high side FET chip of the two or more high side FET chips 350; and a respective metal clip of the two or more metal clips 360. Each of the two or more driver devices connects to a same Vcc pin 301, a same TMON pin 303, a same AGND pin 305, and a same PVcc pin 307 so as to reduce the width of the semiconductor package 200.

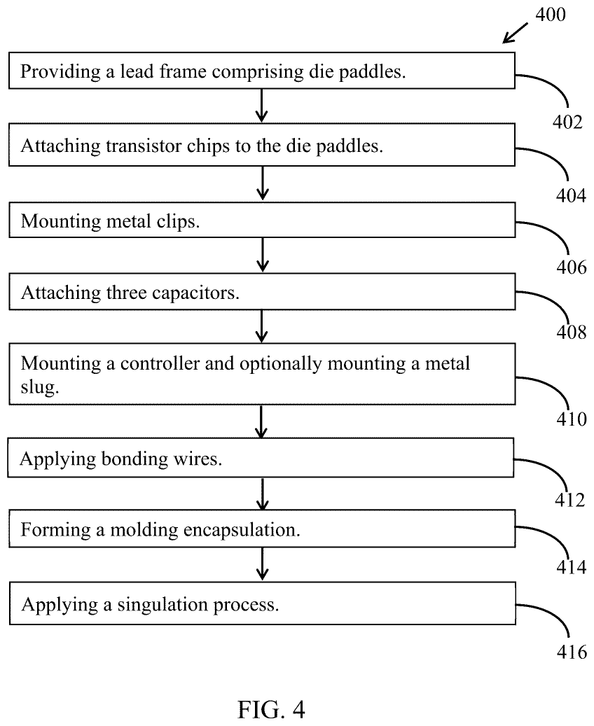

FIG. 4 is a flowchart of a process 400 to develop a semiconductor package in examples of the present disclosure. The process 400 may start from block 402.

In block 402, referring now to FIG. 5A, a lead frame 220 is provided. The lead frame 220 comprises a first die paddle 522 and a second die paddle 524. The lead frame 220 further comprises a first boot pin 311, a second boot pin 312, a first switch node voltage (VSWH) pin 317, and a second VSWH pin 318. The lead frame 220 still further comprises a first input voltage (Vᵢₙ) pin 313, a second Vᵢₙ pin 314, a first output voltage PGND pin 315, a second PGND pin 316, a first VSWH pin 317, and a second VSWH pin 318. Block 402 may be followed by block 404.

In block 404, referring now to FIG. 5B, two or more low side FET chips 340 are attached to the first die paddle 522 and two or more high side FET chips 350 are attached to the second die paddle 524 by printed solder material layer. Each low side FET chip of the two or more low side FET chips 340 is flipped and attached to the first die paddle 522. Each low side FET chip of the two or more low side FET chips 340 comprises a source electrode 340S of FIG. 3B and a gate electrode 340G on a top surface of said each low side FET chip of the two or more low side FET chips 340. Each low side FET chip of the two or more low side FET chips 340 comprises a drain electrode 340D on a bottom surface of said each low side FET chip of the two or more low side FET chips 340.

Each high side FET chip of the two or more high side FET chips 350 is attached to the second die paddle 524. Each high side FET chip of the two or more high side FET chips 350 comprises a source electrode 350S of FIG. 3B and a gate electrode 350G on a top surface of said each high side FET chip of the two or more high side FET chips 350.

The two or more high side FET chips 350 comprises a first high side FET chip 352 comprising a VSWH pad 353 of FIG. 3B, and a second high side FET chip 354 comprising a VSWH pad 355. Block 404 may be followed by block 406.

In block 406, referring now to FIG. 5C, two or more metal clips 360 are mounted by dispensed solder material layer. Each metal clip of the two or more metal clips 360 connects the drain electrode 340D of FIG. 3B of a respective low side FET chip of the two or more low side FET chips 340 to the source electrode 350S of a respective high side FET chip of the two or more high side FET chips 350.

The two or more metal clips 360 comprises a first metal clip 362 of FIG. 3B and a second metal clip 364. The first metal clip 362 electrically connects the VSWH pad 353 of the first high side FET chip 352 to the first VSWH pin 317 of the lead frame 220. The second metal clip 364 electrically connects the VSWH pad 355 of the second high side FET chip 354 to the second VSWH pin 318 of the lead frame 220. Block 406 may be followed by block 408.

In block 408, referring now to FIG. 5D, a first bootstrap capacitor 371, a second bootstrap capacitor 372, and an input capacitor 373 are attached to the lead frame 220. The first bootstrap capacitor 371 comprises a first side electrically connecting with the first boot pin 311 of the lead frame 220, and a second side electrically connecting with the VSWH pad 353 of FIG. 3B of the first high side FET chip 352. The second bootstrap capacitor 372 comprises a first side electrically connecting with the second boot pin 312 of the lead frame 220, and a second side electrically connecting with the VSWH pad 355 of FIG. 3B of the second high side FET chip 354.

The input capacitor 373 comprises a first side electrically connecting with the first Vᵢₙ pin 313 of the lead frame 220 and the second Vᵢₙ pin 314 of the lead frame 220, and a second side electrically connecting with the first PGND pin 315 of the lead frame 220 and the second PGND pin 316 of the lead frame 220.

In examples of the present disclosure, the semiconductor package 200 consists of three capacitors only (the first bootstrap capacitor 371, the second bootstrap capacitor 372, and the input capacitor 373). The semiconductor package 200 excludes a fourth capacitor.

No capacitors, other than the input capacitor 373, is between the first Vᵢₙ pin 313 of the lead frame 220 and the first PGND pin 315 of the lead frame 220, and is between the second Vᵢₙ pin 314 of the lead frame 220 and the second PGND pin 316 of the lead frame 220.

In examples of the present disclosure, the input capacitor 373 is positioned above a center of the lead frame 220. Block 408 may be followed by block 410.

In block 410, referring now to FIG. 5E, an IC chip 382 is mounter by non-conductive epoxy layer and a metal slug 280 is optionally mounted. The metal slug 280 is positioned above the two or more low side FET chips 340. Each metal clip of the two or more metal clips 360 is attached to the metal slug 280. The IC chip 382 is positioned above the two or more high side FET chips 350. Each metal clip of the two or more metal clips 360 is attached to the IC chip 382. Block 410 may be followed by block 412.

In block 412, referring now to FIG. 5F, a plurality of bond wires 389 are attached. The plurality of bond wires 389 connect the IC chip 382 to the plurality of leads 287 of the lead frame 220 as well as the gates of high side FET chips 350. Block 412 may be followed by block 414.

In block 414, referring now to FIG. 5G, a molding encapsulation 290 is formed. The molding encapsulation 290 encloses the two or more low side FET chips 340, the two or more high side FET chips 350, the two or more metal clips 360, the IC chip 382, the first bootstrap capacitor 371, the second bootstrap capacitor 372, the input capacitor 373, the plurality of bond wires 389, and a majority portion of the lead frame 220. In examples of the present disclosure, the majority portion refers to a percentage larger than 50%. The molding encapsulation 290 may further encloses a majority portion of the metal slug 280.

A first significant portion of a bottom surface of the first die paddle 522 is exposed from the molding encapsulation 290. A second significant portion of a bottom surface of the second die paddle 524 is exposed from the molding encapsulation 290. In examples of the present disclosure, the first significant portion refers to a percentage larger than 90%. The second significant portion refers to a percentage larger than 90%. A top surface of the metal slug 280 is exposed from the molding encapsulation 290. Block 414 may be followed by block 416.

In block 416, a singulation process 209 is applied so as to separate the semiconductor package 200 from adjacent semiconductor packages 201 and 203.

Those of ordinary skill in the art may recognize that modifications of the embodiments disclosed herein are possible. For example, a number of bond wires may vary. Other modifications may occur to those of ordinary skill in this art, and all such modifications are deemed to fall within the purview of the present invention, as defined by the claims.

1. A semiconductor package comprising:
a lead frame comprising:
a first die paddle, and
a second die paddle;
two or more low side field-effect transistor (FET) chips, each low side FET chip of the two or more low side FET chips being flipped and attached to the first die paddle, said each low side FET chip of the two or more low side FET chips comprising:
a source electrode and a gate electrode on a top surface of said each low side FET chip of the two or more low side FET chips, and
a drain electrode on a bottom surface of said each low side FET chip of the two or more low side FET chips;
two or more high side FET chips, each high side FET chip of the two or more high side FET chips being attached to the second die paddle, said each high side FET chip of the two or more high side FET chips comprising:
a source electrode and a gate electrode on a top surface of said each high side FET chip of the two or more high side FET chips, and
a drain electrode on a bottom surface of said each high side FET chip of the two or more high side FET chips;
two or more metal clips, each metal clip of the two or more metal clips connecting the drain electrode of a respective low side FET chip of the two or more low side FET chips to the source electrode of a respective high side FET chip of the two or more high side FET chips;
an integrated circuit (IC) chip attached to at least one top of two or more tops of the two or more metal clips;
one or more capacitors;
a plurality of bond wires, and
a molding encapsulation enclosing the two or more low side FET chips, the two or more high side FET chips, the two or more metal clips, the IC chip, the one or more capacitors, the plurality of bond wires, and a majority portion of the lead frame.

2. The semiconductor package of claim 1, wherein the one or more capacitors comprises:
an input capacitor comprising:
a first side connected to the first die paddle, and
a second side connected to the second die paddle.

3. The semiconductor package of claim 2, wherein the input capacitor is disposed at a central area between the two or more low side FET chips and the two or more high side FET chips.

4. The semiconductor package of claim 2, wherein the lead frame further comprises:
a first boot pin,
a second boot pin,
a first switch node voltage (VSWH) pin, and
a second VSWH pin,
wherein the two or more high side FET chips comprise:
a first high side FET chip comprising:
a VSWH pad, and
a second high side FET chip comprising:
a VSWH pad,
wherein the one or more capacitors further comprises:
a first bootstrap capacitor comprising:
a first side electrically connecting with the first boot pin of the lead frame, and
a second side electrically connecting with the VSWH pad of the first high side FET chip, and
a second bootstrap capacitor comprising:
a first side electrically connecting with the second boot pin of the lead frame, and
a second side electrically connecting with the VSWH pad of the second high side FET chip.

5. The semiconductor package of claim 4, wherein the two or more metal clips comprises:
a first metal clip electrically connecting the VSWH pad of the first high side FET chip to the first VSWH pin of the lead frame, and
a second metal clip electrically connecting the VSWH pad of the second high side FET chip to the second VSWH pin of the lead frame.

6. The semiconductor package of claim 5, wherein the IC chip is attached to a top of the first metal clip and a top of the second metal clip above the first high side FET chip and the second high side FET chip.

7. The semiconductor package of claim 2, wherein the lead frame further comprises:
a first input voltage (Vᵢₙ) pin,
a second Vᵢₙ pin,
a first output voltage power ground (PGND) pin, and
a second PGND pin, and
wherein the input capacitor comprises:
a first side electrically connecting with the first Vᵢₙ pin of the lead frame and the second Vᵢₙ pin of the lead frame, and
a second side electrically connecting with the first PGND pin of the lead frame and the second PGND pin of the lead frame.

8. The semiconductor package of claim 7, wherein no capacitors, other than the input capacitor, is between the first Vᵢₙ pin of the lead frame and the first PGND pin of the lead frame, and is between the second Vᵢₙ pin of the lead frame and the second PGND pin of the lead frame.

9. The semiconductor package of claim 1, wherein the one or more capacitors comprises an input capacitor positioned above a center of the lead frame.

10. The semiconductor package of claim 1 further comprising:
a metal slug positioned above the two or more low side FET chips,
wherein said each metal clip of the two or more metal clips is attached to the metal slug; and
wherein the molding encapsulation further encloses a majority portion of the metal slug.

11. A method for fabricating a semiconductor package, the method comprising the steps of: providing a lead frame comprising
a first die paddle; and
a second die paddle;
attaching two or more low side field-effect transistor (FET) chips to the first die paddle, each low side FET chip of the two or more low side FET chips being flipped, said each low side FET chip of the two or more low side FET chips comprising:
a source electrode and a gate electrode on a top surface of said each low side FET chip of the two or more low side FET chips, and
a drain electrode on a bottom surface of said each low side FET chip of the two or more low side FET chips,
attaching two or more high side FET chips to the second die paddle, each high side FET chip of the two or more high side FET chips comprising:
a source electrode and a gate electrode on a top surface of said each high side FET chip of the two or more high side FET chips, and
a drain electrode on a bottom surface of said each high side FET chip of the two or more high side FET chips;
mounting two or more metal clips so as to connect the drain electrode of a respective low side FET chip of the two or more low side FET chips to the source electrode of a respective high side FET chip of the two or more high side FET chips by each metal clip of two or more metal clips;
attaching a first capacitor, a second capacitor, and an input capacitor to the lead frame;
connecting said each metal clip of the two or more metal clips to an integrated circuit (IC) chip positioned above the two or more high side FET chips;
applying a wire bonding process;
forming a molding encapsulation enclosing the two or more low side FET chips, the two or more high side FET chips, the two or more metal clips, the IC chip, and a majority portion of the lead frame; and
applying a singulation process separating the semiconductor package from adjacent semiconductor packages.

12. The method of claim 11, after the step of attaching the first capacitor, the second capacitor, and the input capacitor to the lead frame, further comprising the step of:
connecting said each metal clip of the two or more metal clips to a metal slug positioned above the two or more low side FET chips;
wherein the molding encapsulation further encloses a majority portion of the metal slug.

13. The method of claim 11, wherein the lead frame further comprises:
a first boot pin,
a second boot pin,
a first switch node voltage (VSWH) pin, and
a second VSWH pin,
wherein the two or more high side FET chips comprise:
a first high side FET chip comprising:
a VSWH pad, and
a second high side FET chip comprising:
a VSWH pad,
wherein the first capacitor is a first bootstrap capacitor;
wherein the second capacitor is a second bootstrap capacitor;
wherein the first bootstrap capacitor comprises:
a first side electrically connecting with the first boot pin of the lead frame, and
a second side electrically connecting with the VSWH pad of the first high side FET chip, and
wherein the second bootstrap capacitor comprises:
a first side electrically connecting with the second boot pin of the lead frame, and
a second side electrically connecting with the VSWH pad of the second high side FET chip.

14. The method of claim 13, wherein the two or more metal clips comprises:
a first metal clip electrically connecting the VSWH pad of the first high side FET chip to the first VSWH pin of the lead frame, and
a second metal clip electrically connecting the VSWH pad of the second high side FET chip to the second VSWH pin of the lead frame.

15. The method of claim 11, wherein the lead frame further comprises:
a first input voltage (Vᵢₙ) pin,
a second Vᵢₙ pin,
a first output voltage power ground (PGND) pin, and
a second PGND pin, and
wherein the input capacitor comprises:
a first side electrically connecting with the first Vᵢₙ pin of the lead frame and the second Vᵢₙ pin of the lead frame, and
a second side electrically connecting with the first PGND pin of the lead frame and the second PGND pin of the lead frame.

16. The method of claim 15, excluding a fourth capacitor.

17. The method of claim 15, wherein no capacitors, other than the input capacitor, is between the first Vᵢₙ pin of the lead frame and the first PGND pin of the lead frame, and is between the second Vᵢₙ pin of the lead frame and the second PGND pin of the lead frame.

18. The method of claim 11, wherein the input capacitor is positioned above a center of the lead frame.

19. The method of claim 11 further comprising two or more driver devices;
wherein each driver device of the two or more driver devices comprises:
a respective low side FET chip of the two or more low side FET chips;
a respective high side FET chip of the two or more high side FET chips; and
a respective metal clip of the two or more metal clips.

20. The method of claim 19, wherein each of the two or more driver devices connects to a same Vcc pin, a same TMON pin, a same AGND pin, and a same PVcc pin.
